(19) United States
(12) Patent Application Publication
(10) Pub. No.: US 2015/0147883 A1
(43) Pub. Date: May 28, 2015

(54) Post-CMP Cleaning and Apparatus for Performing the Same

(71) Applicant: Taiwan Semiconductor Manufacturing Company, Ltd., Hsin-Chu (TW)

(72) Inventor: Hui-Chi Huang, Zhubei City (TW)

(73) Assignee: TAIWAN SEMICONDUCTOR MANUFACTURING COMPANY, LTD., Hsin-Chu (TW)

(21) Appl. No.: 14/087,367

(22) Filed: Nov. 22, 2013

(51) Int. Cl. H01L 21/02; H01L 21/306; H01L 21/67

(52) U.S. Cl. CPC H01L 21/02057; H01L 21/67023; H01L 21/30625
USPC 438/692; 134/34; 134/135

(57) ABSTRACT

A method of performing a post Chemical Mechanical Polish (CMP) cleaning includes picking up the wafer, spinning a cleaning solution contained in a cleaning tank, and submerging the wafer into the cleaning solution, with the cleaning solution being spun when the wafer is in the cleaning solution. After the submerging the wafer into the cleaning solution, the wafer is retrieved out of the cleaning solution.

### BACKGROUND

Chemical mechanical Polish (CMP) processes are widely used in the fabrication of integrated circuits. When an integrated circuit is built up layer by layer on the surface of a semiconductor wafer, CMP processes are used to planarize the topmost layer to provide a planar surface for subsequent fabrication steps. CMP processes are carried out polishing the wafer surface against a polish pad. A slurry containing both abrasive particles and reactive chemicals is applied to the polish pad. The relative movement of the polish pad and wafer surface coupled with the reactive chemicals in the slurry allows the CMP process to planarize the wafer surface by means of both physical and chemical forces.

CMP processes can be used for the fabrication of various components of an integrated circuit. For example, CMP processes may be used to planarize inter-level dielectric layers and inter-metal dielectric layers. CMP processed are also commonly used in the formation of the copper lines that interconnect the components of integrated circuits.

After a CMP process, the surface of the wafer, on which the CMP process has been performed, is cleaned to remove residues. The residues may include organic matters and particles. In recent generations of integrated circuits, the sizes of the integrated circuit devices are reduced to a very small scale. This posts a demanding requirement to the post-CMP cleaning than for older generations of integrated circuits. For example, the sizes of the metal particles that remain after the post-CMP cleaning cannot exceed a half of the critical dimension (the gate length) of the transistors on the wafer. Obviously, with the reduction of the sizes of the integrated circuit devices, such requirement is tightened.

In conventional post-CMP cleaning, brushes were used to remove the residues on the wafers. The brushes are typically formed of sponges. However, the brushes have large sizes, and some portions of the wafers may be left without being cleaned. For example, during the cleaning, the positions of the sponges may shift. The sponges may also age with time, or may be damaged. This may cause some parts of the wafer not to be able to touch the sponge, and hence the residue is not cleaned thoroughly. In another type of post-CMP cleaning, pencil-type brushes were used. The pencil-type brushes have small sizes, and hence the wafers cleaned using the pencil-type brushes are less likely to have residues left un-cleaned. The throughput of the post-CMP cleaning using pencil-type brushes, however, is low.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1 illustrate a Chemical Mechanical Process (CMP) performed on a front surface of a semiconductor wafer in accordance with some exemplary embodiments;

FIG. 2 illustrates a perspective view of a cleaning apparatus in accordance with some embodiments;

FIGS. 3A through 3E are bottom views of various vacuum heads in accordance with some embodiments;

FIGS. 4 and 5 illustrate a perspective view and a cross-sectional view, respectively, in a post-CMP cleaning process in accordance with some alternative exemplary embodiments, wherein the cleaning apparatus includes a cleaning tank having a whipping-top shape;

FIG. 6 illustrates a cross-sectional view in a post-CMP cleaning process in accordance with some alternative exemplary embodiments, wherein the cleaning apparatus includes a cleaning tank having a cone shape; and

FIGS. 7 and 8 illustrate a perspective view and a cross-sectional view, respectively, in a post-CMP cleaning process in accordance with some alternative exemplary embodiments, wherein a cleaning apparatus including a cleaning tank having a cylinder shape is used.

### DETAILED DESCRIPTION OF ILLUSTRATIVE EMBODIMENTS

The making and using of the embodiments of the disclosure are discussed in detail below. It should be appreciated, however, that the embodiments provide many applicable concepts that can be embodied in a wide variety of specific contexts. The specific embodiments discussed are illustrative, and do not limit the scope of the disclosure.

A method for performing post Chemical Mechanical Polish (CMP) cleaning and the apparatus for forming the same are provided in accordance with various exemplary embodiments. The variations of the embodiments are discussed. Throughout the various views and illustrative embodiments, like reference numbers are used to designate like elements.

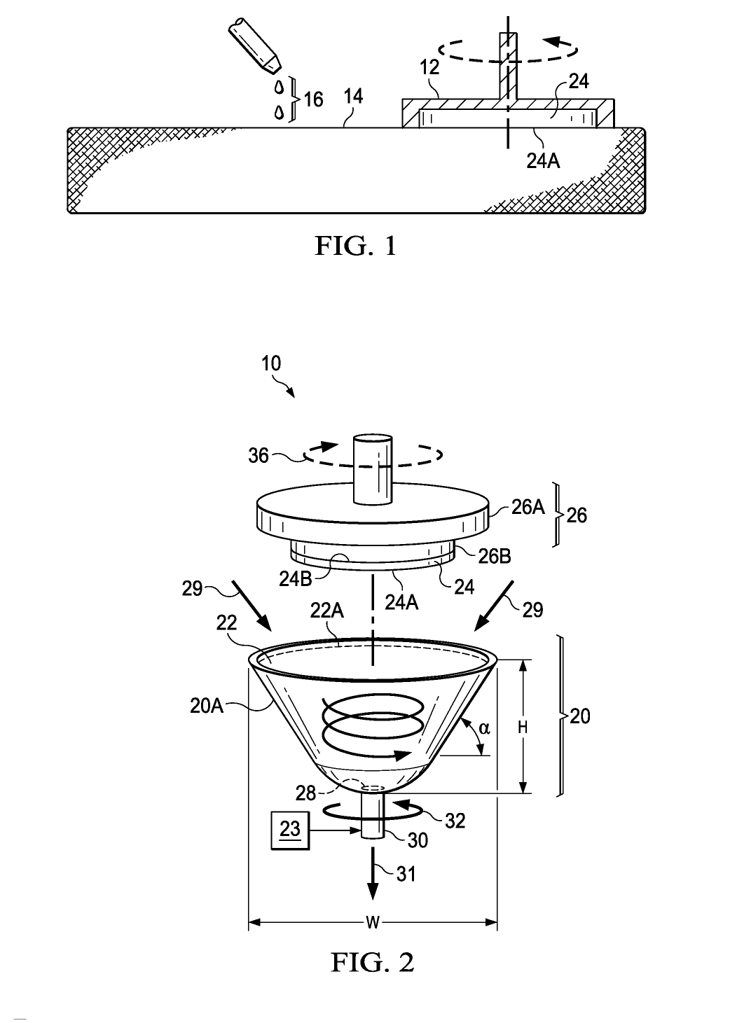

FIG. 1 illustrates a CMP performed on front surface 24A of semiconductor wafer 24 in accordance with some exemplary embodiments. The CMP is used to planarize front surface 24A for subsequent fabrication steps. Wafer is held by in carrier 12 that presses the front surface 24A of wafer 24 against polishing pad 14, which is attached to a platen disk (not shown). Both the platen disk and wafer carrier 12 are rotated while slurry 16 containing both abrasive particles and reactive chemicals is applied to polishing pad 14. The slurry is transported to surface 24A of wafer 24 via the rotation of the porous polishing pad 14. The relative movement of polishing pad 14 and wafer 24 coupled with the reactive chemicals in the slurry allows surface 24A of wafer 24 to be planarized by means of both physical and chemical forces.

The CMP can be used at various stages during the fabrication of the integrated circuit on wafer 24. For example, the CMP may be used to planarize copper lines and the respective low-k dielectric layers that interconnect components of the integrated circuits on wafer 24. The CMP may also be used to planarize wafer 24 in the formation of shallow trench isolation regions, in the formation of Shallow Trench Isolation (STI) regions, and the like.

After the CMP, wafer 24 is cleaned through a post-CMP cleaning step. FIG. 2 illustrates a perspective view of a stage in the post-CMP cleaning in accordance with some embodiments. The cleaning apparatus 10 includes cleaning tank 20, which is used to hold cleaning solution 22. Cleaning tank 20 is configured to rotate (represented by arrow 32), and is configured to drive the cleaning solution 22 therein to spin along with the rotation of cleaning tank 20. Cleaning tank 20 may have a design that its top with W1 is greater than the widths of lower portions. Width W1 may also be a diameter when cleaning tank 20 has a circular top-view shape. Furthermore, from the top to the bottom of cleaning tank 20, the widths of cleaning tank 20 may gradually and continuous reduce. For example, FIG. 2 illustrates a whipping-top type tank, wherein at least parts of the edges 20A (in the cross-sectional view) are curved.

Cleaning solution 22 includes various types, wherein different types of cleaning solution 22 may be used to clean different residues on wafers. In accordance with some embodiments, cleaning solution 22 includes water with no chemicals intentionally added. Cleaning solution 22 may also be deionized water. In alternative embodiments, cleaning solution 22 includes an acid aqueous solution, which may include an organic acid such as citric acid, an inorganic acid such as HNO₃, or the like. In yet alternative embodiments, cleaning solution 22 includes an alkaline aqueous solution, which may include an organic base such as NR₃ (with R being alkyl), an inorganic base such as NH₄OH, or the like. Surfactants such as sodium dodecyl sulfate may be added into cleaning solution 22 to reduce the surface tension of cleaning solution 22. Cleaning solution 22 may include water as a solvent. Alternatively, cleaning solution 22 may use organic solvents such as methanol. Cleaning solution 22 may also be an aqueous solution including peroxide. For example, cleaning solution 22 may include H₂O₂ in water.

Cleaning solution 22 may not be heated, and hence has a temperature between about 15° C. and about 25° C. during the post-CMP cleaning. The cleaning solution 22 may also be heated to a temperature in the range between about 25° C. and about 80° C. With the increased temperature, the efficiency of the cleaning may be improved. Alternatively, a temperature higher than about 80° C. or lower than about 15° C. may be used.

As shown in FIG. 2, the top-view shape of cleaning tank 20 may be rounded, so that wafer 24 may fit in cleaning tank 20 without the requirement of adding excess margin. Top width W1 is selected by adding a small margin, such as 50 mm, to the size of wafer 24. Depending on the size of wafer 24, top width W1 of cleaning tank 20 may be in the range between about 300 mm and about 600 mm, although width W1 may be increased if large wafers are to be cleaned, or reduced if small wafers are to be cleaned. Height H of cleaning tank 20 may be in the range between about 100 mm and about 900 mm. Furthermore, the tilt angle α of slant edges 20A is selected according to the height H and width W1 of cleaning tank 20. Tilt angle α is greater than zero degree and smaller than 90 degrees.

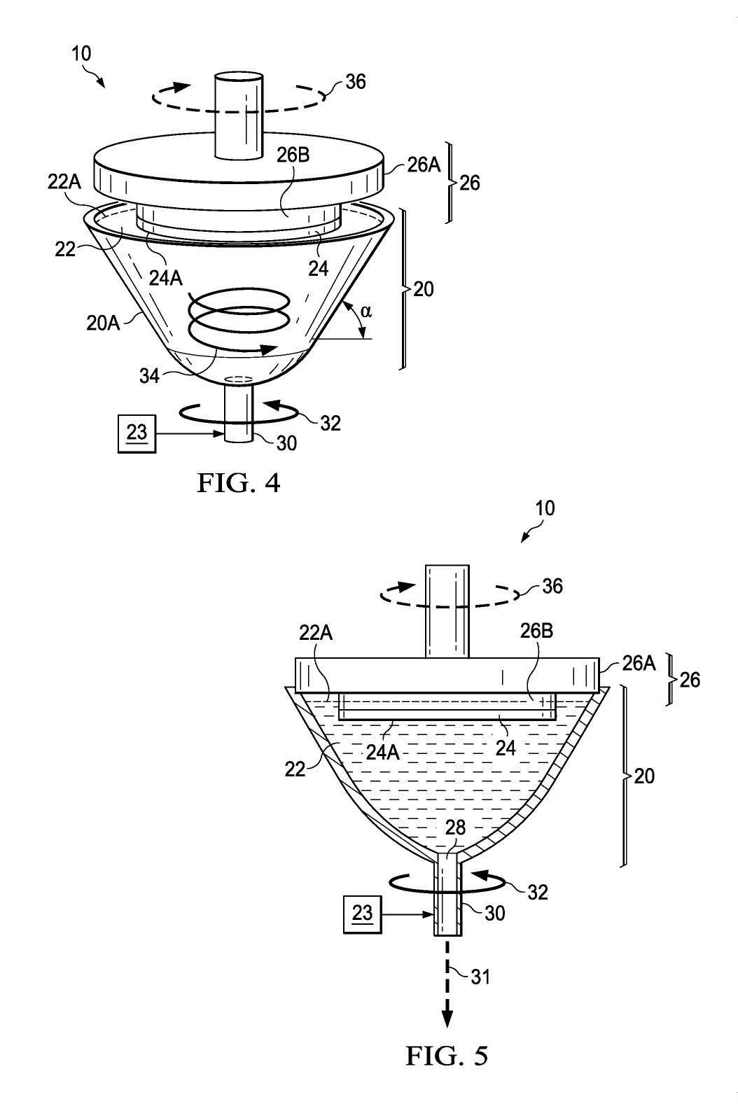

The cleaning apparatus 10 further includes vacuum head 26, which is configured to suck wafer 24 on it through vacuum. Vacuum head 26 is configured to be moved between a first position shown in FIG. 2 and a second position shown in FIG. 4. At the first position, the entire wafer 24 is out of cleaning solution 22. At the second position, the entire wafer 24 is submerged into cleaning solution 22. The tool for generating the vacuum in vacuum head 26, which tool may include a pump, is not illustrated. In accordance with some embodiments, vacuum head 26 includes a larger part 26A, and a smaller part 26B connected to the larger part 26A, with the vacuum channels (not shown) in larger part 26A connected to smaller part 26B. The back surface 24B of wafer 24 is sucked onto vacuum head 26. The front surface 24A of wafer 24 faces down, wherein front surface 24A is the surface that was polished through the CMP shown in FIG. 1. Accordingly, the CMP residues such as organic residues and particles adhered to front surface 24A also face down. In some embodiments, the particles include metal particles.

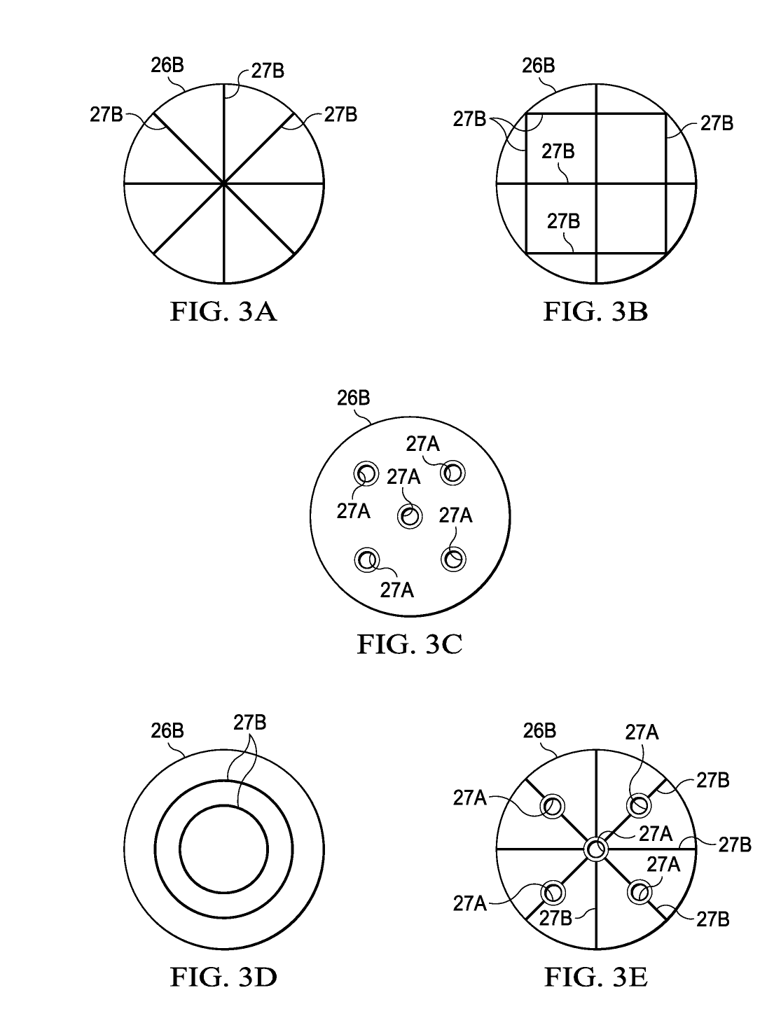

FIGS. 3A through 3E illustrate the configuration of various designs of vacuum head 26, wherein the illustrated view is the bottom view of part 26B of vacuum head 26. Vacuum head 26 may include holes 27A (FIGS. 3C and 3E) and/or slits 27B (FIGS. 3A, 3B, 3D, and 3E), through which air is vacuumed into vacuum head 26. FIG. 3A illustrates that slits 27B have a radiating pattern. FIG. 3B illustrates that slits 27B form a rectangular pattern. In FIG. 3C, a plurality of holes 27A are distributed uniformly on the surface of vacuum head part 26B. FIG. 3D illustrates that slits 27B form rings, with the outer rings encircling inner rings. FIG. 3E includes the combination of the slits 27B in FIG. 3A and the holes 27A in FIG. 3C. Through the suction force provided through holes 27A and/or slits 27B, wafer 24 (FIG. 2) may be sucked onto vacuum head 26.

Referring back to FIG. 2, before wafer 24 is submerged into cleaning solution 22, the particles and the organic residues that are cleaned from the previously cleaned wafers may be drained (represented by arrow 31) out of cleaning tank 20 through outlet 28 and pipe 30. To drain the particles and the organic residues, the rotation of cleaning tank 20 is stopped first. Outlet 28, through which the particles and the organic residues are drained, is located at the bottom of cleaning tank 20. Since cleaning tank 20 has a narrow bottom, the particles and the organic residues are accumulated close to outlet 28. Accordingly, when the particles and the organic residues are drained, a small amount of cleaning solution 22 is drained, while the most of cleaning solution 22 remain in cleaning tank 20. Hence, with cleaning tank 20 having a small bottom, less cleaning solution 22 is wasted. If needed, cleaning solution 22 may be replenished from the top of cleaning tank 20, wherein the replenishing is represented by arrows 29.

Referring to FIG. 4, vacuum head 26 is lowered, so that wafer 24 and at least a portion of vacuum head part 26B are submerged in cleaning solution 22. A cross-sectional view of the structure in FIG. 5 is illustrated in 4, which illustrates that wafer 24 is dipped below the top surface 22A of cleaning solution 22. Referring to FIG. 4, cleaning tank 20 is rotated, as represented by arrow 32. As a result, cleaning solution 22 in cleaning tank 20 spins along with cleaning tank 20. In accordance with some embodiments, cleaning tank 20 and cleaning solution 22 are rotated at a speed between about 5,000 Rotations Per Minute (RPM) and about 40,000 RPM. An exemplary apparatus for rotating cleaning tank 20 is schematically illustrated as driving mechanism 23, which is configured to drive cleaning tank 20 to rotate at the desirable rotation speed. With the rotation of cleaning solution 22, the residue on the front surface of wafer 24 falls off The high-speed rotation of cleaning solution 22 results in a high-gravity field to be generated, which is applied on the residues such as the organic residue and the metal particles. Since wafer 24 has its front surface 24A facing down, the residue falls off from the front surface 24A, and falls to the bottom of cleaning tank 20. The residue accumulates at the bottom of cleaning tank 20, as represented by arrow 34. The gravity field not only pulls off the residue from wafer 24, but also prevents the residue from sticking back to wafer 24. Hence, the efficiency of the post-CMP cleaning in accordance with the embodiments is high.

In some embodiments, vacuum head 26 remains still during the cleaning process, and cleaning solution 22 in cleaning tank 20 spins. In alternative embodiments, when cleaning solution 22 in cleaning tank 20 spins, vacuum head 26 also rotates in a direction opposite to the rotating direction of cleaning tank 20, as illustrated by arrow 36 in FIG. 4. In yet alternative embodiments, cleaning solution 22 and cleaning tank 20 remain still, and vacuum head 26 rotates (arrow 36), for example, with a rotating speed in the range between about 5,000 RPM and about 40,000 RPM.

After the cleaning process as shown in FIGS. 4 and 5, vacuum head 26 is pulled up, and wafer 24 is retrieved out of cleaning solution 20. The respective apparatus 10 is essentially the same as in FIG. 2. At this time, if the residue cleaned from wafer 24 accumulates to certain amount, cleaning tank 20 may stop rotating, and the accumulated residue is drained out of cleaning tank 20. The draining of the residue is performed when needed, and does not need to be performed after the cleaning of every wafer 24. After a wafer is cleaned and lifted out of cleaning solution 22, if the draining is not needed, cleaning tank 20 and cleaning solution 22 may remain rotating, and a subsequent wafer may be submerged for the cleaning.

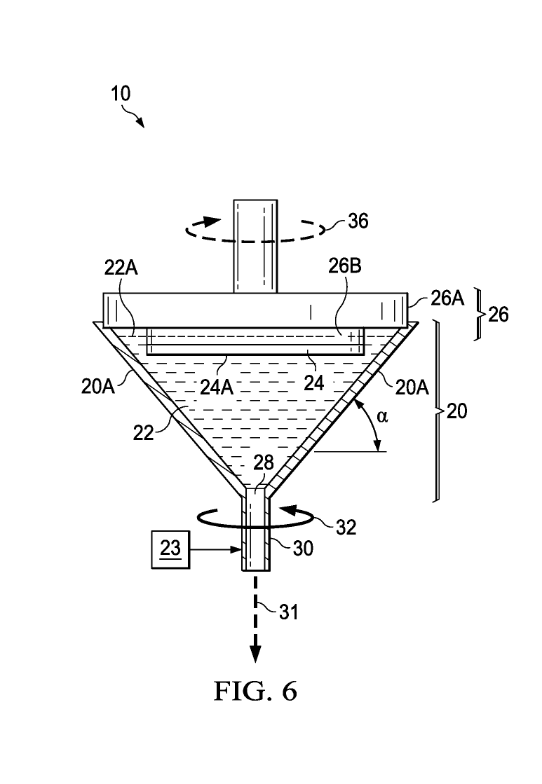

FIG. 6 illustrates the cross-sectional view of cleaning apparatus 10 in accordance with alternative embodiments. The cleaning apparatus 10 in accordance with these embodiments is similar to what is shown in FIG. 2, except that cleaning tank 20 has a cone shape rather than a whipping-top shape. Accordingly, edges 20A of cleaning tank 20 are substantially straight in the cross-sectional view. The cleaning process in these embodiments is essentially the same as shown in FIGS. 2 through 5, and hence is not repeated herein.

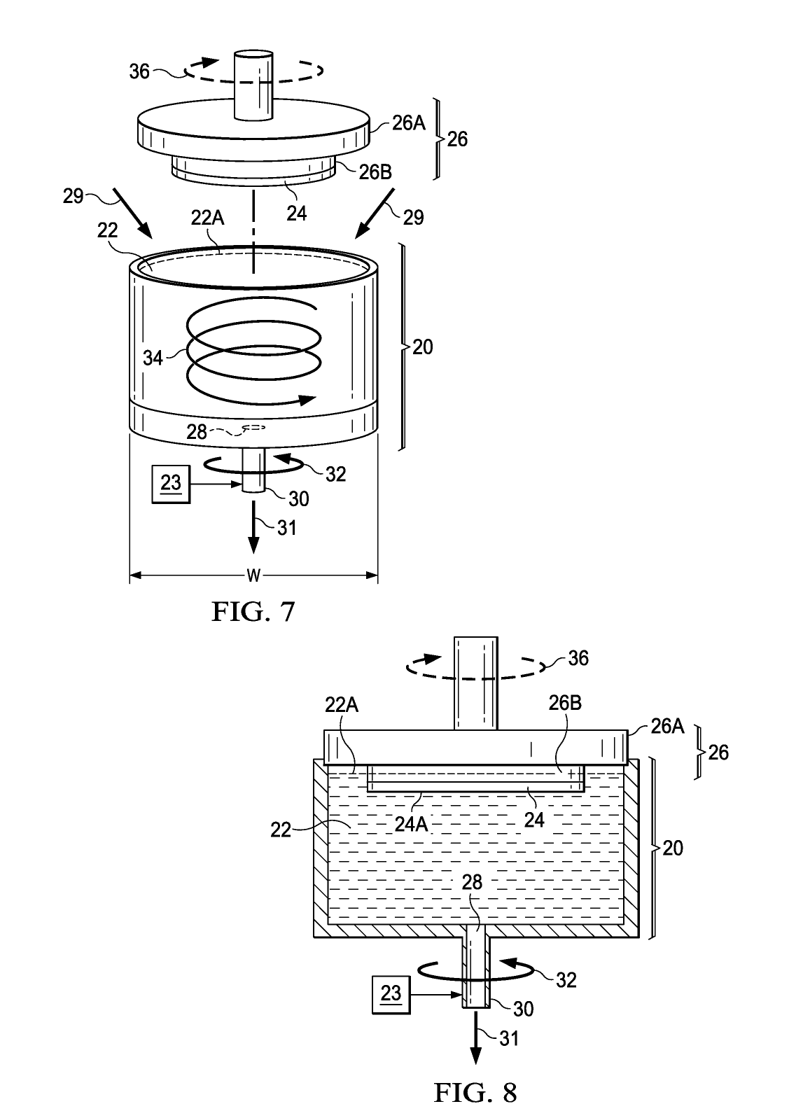

FIGS. 7 and 8 illustrate the cleaning process using cleaning apparatus 10 in accordance with yet alternative embodiments. The cleaning apparatus 10 in accordance with these embodiments is similar to what is shown in FIG. 2, except that cleaning tank 20 has a cylinder shape, rather than a whipping-top shape. Cleaning tank 20 thus has the top width W1 equal to its bottom width. The diameter W1 of cleaning tank 20 in these embodiments may also be in in the range between about 300 mm and about 600 mm, for example, depending on the size of wafer 24 to be cleaned. FIG. 7 illustrates a perspective view of cleaning apparatus 10 before wafer 24 is submerged into cleaning solution 22. FIG. 8 illustrates a cross-sectional view when wafer 24 is submerged into cleaning solution 22. Again, the residue on the front surface of wafer 24 is cleaned through the gravity field applied on the residue, which gravity field is applied through the spinning of cleaning solution 22. The cleaning process in these embodiments is essentially the same as shown in FIGS. 2 through 5, and hence is not repeated herein.

The embodiments of the present disclosure have some advantageous features, during the cleaning process, no brush (which is formed of sponge, for example) or pencil-type sponge is used, hence, the problems existing in conventional cleaning process, which problems involve the inadequate contact of brush to wafer and the low throughput of pencil-type sponge, are eliminated. Experiment results indicated that small particles having sizes between about 10 nm and about 150 nm, and organic residues having sizes between about 0.04 μm and about 5 μm, have been successfully removed.

In accordance with some embodiments, a method of performing a post-CMP cleaning includes picking up the wafer, spinning a cleaning solution contained in a cleaning tank, and submerging the wafer into the cleaning solution, with the cleaning solution being spun when the wafer is in the cleaning solution. After the submerging the wafer into the cleaning solution, the wafer is retrieved out of the cleaning solution.

In accordance with other embodiments, a method includes performing a CMP to planarize a front surface of a wafer, and rotating a cleaning tank, wherein a cleaning solution is contained in the cleaning tank. The cleaning solution spins along with the cleaning tank. The method further includes cleaning the wafer by submerging the wafer into the cleaning solution. The front surface of the wafer faces a bottom of the cleaning tank. The cleaning tank spins when the wafer is in the cleaning solution. After cleaning, the wafer is retrieved out of the cleaning solution.

In accordance with yet other embodiments, an apparatus for performing an after-CMP cleaning includes a cleaning tank configured to hold liquid, wherein the cleaning tank is configured to rotate, and a vacuum head facing toward the cleaning tank. The vacuum head is configured to move between a first position and a second position, wherein at the first position, a wafer picked up by the vacuum head is fully out of a solution in the cleaning tank, and at the second position, the wafer is fully submerged in the solution.

Although the embodiments and their advantages have been described in detail, it should be understood that various changes, substitutions and alterations can be made herein without departing from the spirit and scope of the embodiments as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A method comprising:
picking up a wafer;
spinning a cleaning solution contained in a cleaning tank;
submerging the wafer into the cleaning solution, with the cleaning solution spun when the wafer is in the cleaning solution; and
after the submerging the wafer into the cleaning solution, retrieving the wafer out of the cleaning solution.

2. The method of claim 1, wherein the wafer has a front surface facing down when the wafer is in the cleaning solution.

3. The method of claim 1, wherein the cleaning solution is spun at a speed in a range between about 5,000 Rotations per Minute (RPM) and about 40,000 RPM.

4. The method of claim 1, wherein during the submerging the wafer into the cleaning solution, the wafer remains un-rotated.

5. The method of claim 1, wherein during the submerging the wafer into the cleaning solution, the wafer is rotated in a direction opposite to a direction the cleaning solution is spun.

6. The method of claim 1, wherein during the submerging the wafer into the cleaning solution, the cleaning solution is heated to a temperature in a range between about 25° C. and about 80° C.

7. The method of claim 1 further comprising, before picking up the wafer and submerging the wafer into the cleaning solution, performing a Chemical Mechanic Polish (CMP) to planarize a front surface of the wafer, wherein during the submerging the wafer into the cleaning solution, the front surface of the wafer faces toward a bottom of the cleaning tank.

8. A method comprising:
performing a Chemical Mechanic Polish (CMP) to planarize a front surface of a wafer;
rotating a cleaning tank, wherein a cleaning solution is contained in the cleaning tank, and wherein the cleaning solution spins along with the cleaning tank;
cleaning the wafer by submerging the wafer into the cleaning solution, wherein the front surface of the wafer faces a bottom of the cleaning tank, and wherein the cleaning tank spins when the wafer is in the cleaning solution; and
after the submerging the wafer into the cleaning solution, retrieving the wafer out of the cleaning solution.

9. The method of claim 8, wherein the cleaning tank has increasingly reduced diameters from a top end to a bottom end of the cleaning tank, wherein residues on the front surface of the wafer accumulates to the bottom end of the cleaning tank, and wherein the method further comprises, after retrieving the wafer out of the cleaning solution, draining the residues through an outlet at the bottom end of the cleaning tank.

10. The method of claim 8, wherein the cleaning tank spins at a speed in a range between about 5,000 Rotations Per Minute (RPM) and about 40,000 RPM.

11. The method of claim 8, wherein during the submerging the wafer into the cleaning solution, the wafer remains un-rotated.

12. The method of claim 8, wherein the cleaning solution comprises water with no chemicals added therein.

13. The method of claim 8, wherein the cleaning solution comprises an acid aqueous or an organic solution.

14. The method of claim 8, wherein the cleaning solution comprises an alkaline aqueous or an organic solution.

15. An apparatus comprising:
a cleaning tank configured to hold liquid, wherein the cleaning tank is configured to rotate; and
a vacuum head facing toward the cleaning tank, wherein the vacuum head is configured to move between a first position and a second position, wherein at the first position, a wafer picked up by the vacuum head is fully out of a solution in the cleaning tank, and at the second position, the wafer is fully submerged in the solution.

16. The apparatus of claim 15, wherein the cleaning tank has a whipping-top shape, wherein from a top to a bottom of the cleaning tank, diameters of the cleaning tank gradually reduce, and wherein tilted edges of the cleaning tank connecting the top to the bottom of the cleaning tank are curved.

17. The apparatus of claim 15, wherein the cleaning tank has a cone shape, wherein from a top to a bottom of the cleaning tank, diameters of the cleaning tank gradually reduce, and wherein tilted edges of the cleaning tank connecting the top to the bottom of the cleaning tank are straight.

18. The apparatus of claim 15, wherein the cleaning tank has a cylinder shape, with a top end and a bottom end of the cleaning tank having a same diameter.

19. The apparatus of claim 15, wherein the cleaning tank comprises an outlet at a bottom of the cleaning tank, and wherein the apparatus further comprises a pipe connected to the outlet.

20. The apparatus of claim 15 further comprising a driving mechanism configured to rotate the cleaning tank at a speed between about 5,000 Rotations per Minute (RPM) and about 40,000 RPM.
